(19) United States
(12) Patent Application Publication
(10) Pub. No.: US 2004/0185648 A1
(43) Pub. Date: Sep. 23, 2004

(54) Diffusion connections for integrated circuits

(76) Inventor: Jeng-Jye Shau, Palo Alto, CA (US)

Correspondence Address: Bo-In Lin, 13445 Mandoli Drive, Los Altos Hills, CA, 94022, US

(21) Appl. No.: 10/391,380

(22) Filed: Mar. 17, 2003

(51) Int. Cl. H01L 21/425; H01L 21/44

(52) U.S. Cl. 438/597; 438/682

(57) ABSTRACT

Integrated circuit (IC) manufacture procedures are developed to reduce connected diffusion areas. Using a diffusion connection layer that is deposited immediately on exposed diffusion areas, high quality electrical connection is achieved while avoiding critical contact design rules. The resulting procedure provides 20%-40% area reduction for most of integrated circuits. Significant improvements in power and performance also can be achieved.

### BACKGROUND OF THE INVENTION 1. Field of the Invention

The present invention relates to integrated circuit (IC) manufacture procedures, especially on methods to manufacture diffusion connections. 2. Description of the Related Art

IC technologies are often characterized by transistor channel length. For example, a 0.13 m technology means the technology provides transistors with minimum gate length of 0.13 m. While transistor gate length is the key parameter in determining the performance and cost of an IC technology, the other two terminals—source and drain diffusion areas—also have major impacts on performance/cost of Integrated circuits.

FIG. 1 shows the structures of three prior art IC transistors (T1, T2, T3). Transistors T1 and T2 share a diffusion area (101) between them. A diffusion contact (103) is dropped between T1 and T2. The minimum spacing (Sgc) allowed between T1 and T2 is confined by the design rules for contact to gate spacing (Scg) and Contact size (Wc). We have Sgc=Wc+Scg+Scg as shown in FIG. 1. Transistors T2 and T3 also share a diffusion area (105) between them, but this diffusion area (105) does not need a contact. The minimum spacing allowed between T2 and T3 is confined by the design rules for gate to gate spacing (Sgg). The diffusion area (107) to the left hand side of T1 also has a contact (108). The minimum size (Sdc) of this diffusion area (107) is confined by the design rules for Wc, Scg, and the minimum spacing between contact and edge of the diffusion area (Scd), where Sdc=Wc+Scg+Scd. The diffusion area (109) to the right hand side of T3 does not have contact. The minimum size of this diffusion area (109) is confined by the design rules for gate to edge of the diffusion (Sgd).

For a typical 0.13 m IC technology, Sgg=0.18 m, Wc=0.16 m, Scg=0.11 m, Scd=0.07 m, Sgd=0.23 m, Sgc=Wc+Scg+Scg=0.38 m, and Sdc=Wc+Scg+Scd=0.34 m. The minimum spacing between nearby transistors is more than doubled (0.38 vs. 0.18) when a contact (103) is placed on the shared diffusion area (101). The minimum size of isolated source/drain area also increases (0.34 vs. 0.23) by nearly 50% when a contact (108) is placed on the diffusion area.

Prior art IC use diffusion contacts (103, 108) to provide connections from the diffusion areas (101, 107) through the first layer metal (M1) to other circuit elements. The practical example in FIG. 1 shows that such prior art diffusion contacts causes significant increase in the sizes of IC transistors. The diffusion contacts also increase the diffusion area, which increase the capacitance of the area. Such increase in capacitance may slow down the speed and/or increase the power consumption of IC. It is therefore highly desirable to provide more efficient diffusion connection methods for cost/performance improvements.

### SUMMARY OF THE INVENTION

The primary objective of this invention is to provide effective methods to reduce the size of diffusion connections. The other objective is to reduce parasitic capacitance of diffusion areas. Another objective is to provide additional interconnection for IC. These and other objectives of the present invention are achieved by methods to manufacture direct diffusion connections.

While the novel features of the invention are set forth with particularly in the appended claims, the invention, both as to organization and content, will be better understood and appreciated, along with other objects and features thereof, from the following detailed description taken in conjunction with the drawings.

### BRIEF DESCRIPTION OF THE DRAWINGS

FIG. 1 shows typical cross section structures of prior art IC;

FIGS. 2(a-f) show cross section views of prior art IC diffusion contact manufacture procedures;

FIGS. 3(a-f) show cross section views for diffusion contact manufacture procedures of the present invention;

FIGS. 4(a,b) compare layout top views between a prior art NAND gate and a NAND gate of the present invention;

FIGS. 5(a, b) shows an etch-back procedure to define diffusion connection layer of the present invention; and

FIG. 6 illustrates methods for connecting poly lines to diffusion connection layer of the present invention.

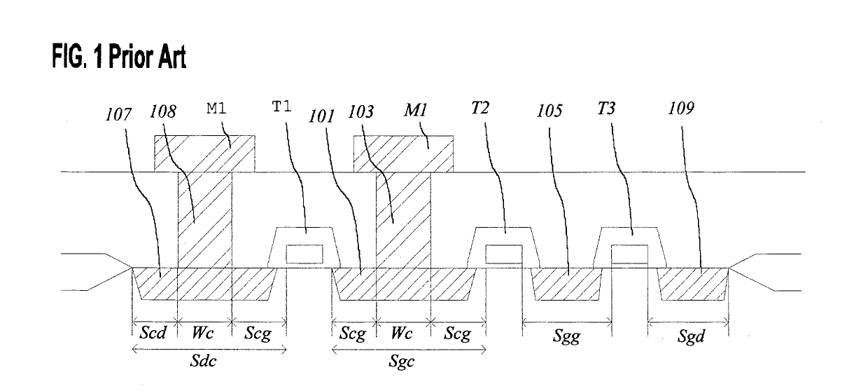

### DETAILED DESCRIPTION OF THE INVENTION

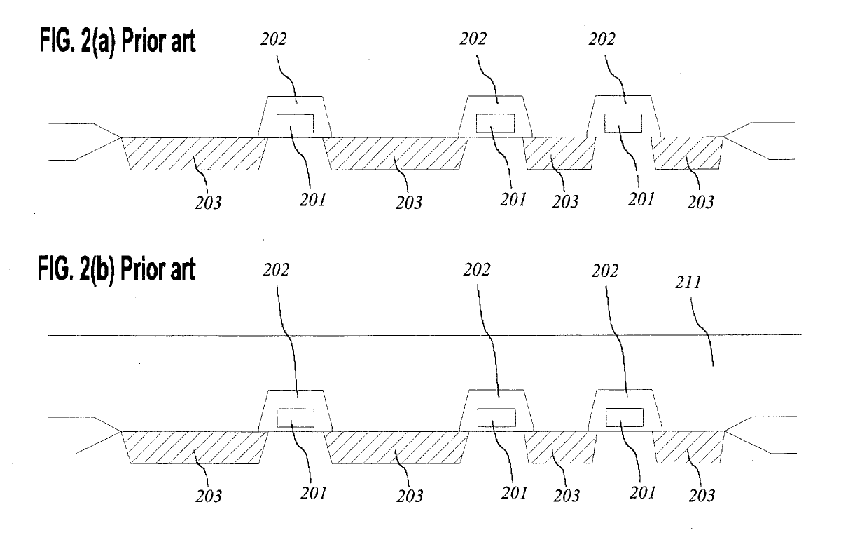

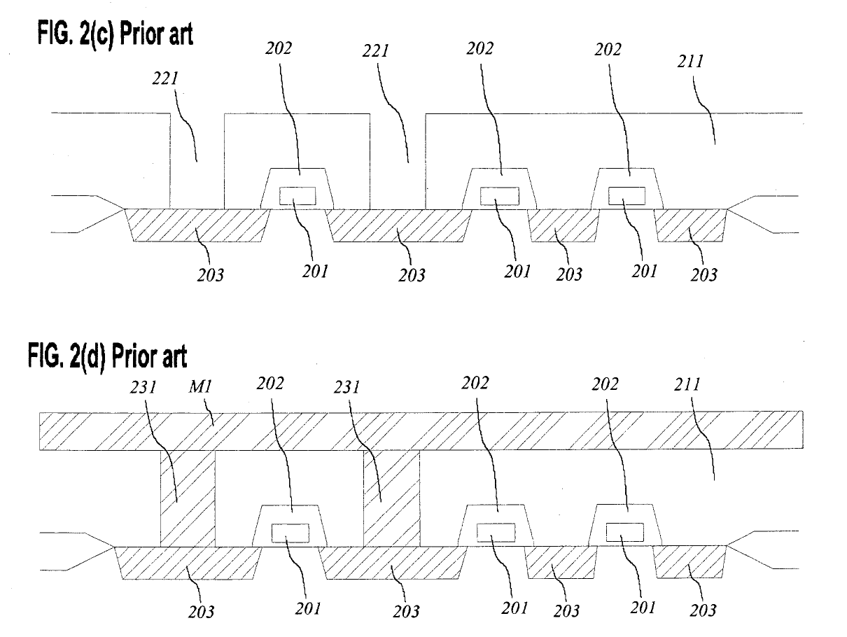

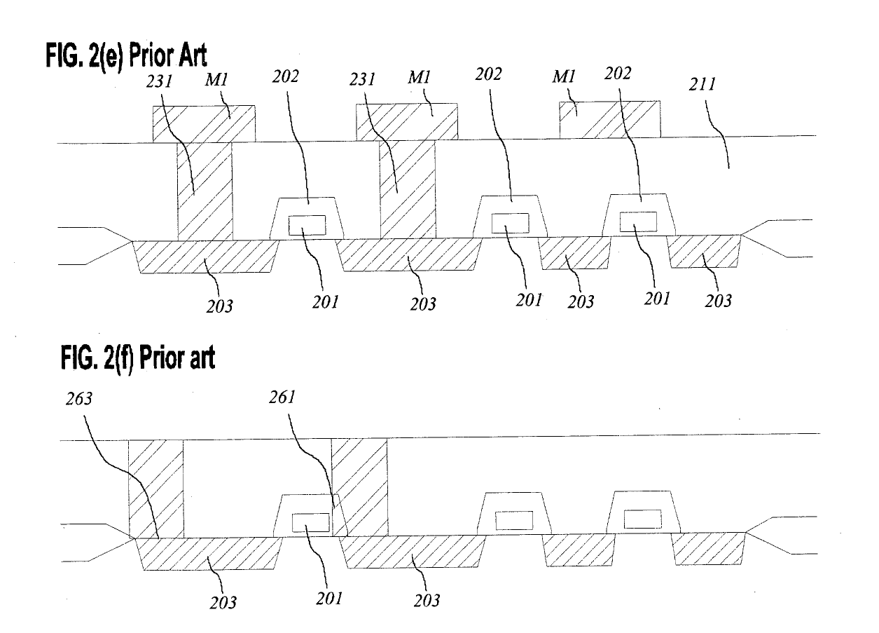

Prior art diffusion contact manufacture procedures are first discussed in FIGS. 2(a-f) to facilitate clear understanding of the present invention. FIG. 2(a) shows the cross-section structures of IC devices at a stage right after formation of transistors. At this stage, the gates (201) of transistor are covered with protection oxide (202). The diffusion areas (203) serve as transistor source or drain terminals are already manufactured, while the surfaces of those diffusion areas (203) are still exposed. For prior art manufacture procedures, the next step is to cover the wafer with insulating layers (211) as shown in FIG. 2(b), then etch contact holes (221) as shown in FIG. 2(c). The next step is to fill the contact holes with conductors (231) and deposit the first layer metal (M1) as shown in FIG. 2(d). Unwanted M1 is etched away to form proper circuit connections as shown in FIG. 2(e). The manufacture procedures after M1 are not shown for simplicity. FIGS. 2(a-e) show the cross section structures when the alignments for all the etching steps are perfect. In reality, no alignments can be perfect. FIG. 2(f) shows the situation when the contact hole etching alignment is off. We can see that it is possible to have contact-to-gate short circuit (261) if we did not reserve enough tolerance for contact to gate spacing. We also can have partial contact connection (263) if we did not reserve enough tolerance for contact to diffusion edge spacing. This partial contact (263) has abnormally high resistance and it also may cause short circuit to the substrate. The possibility of causing such manufacture defects (261, 263) is the reason why we need to have design rules forcing IC designers to reserve enough tolerances by increasing sizes of connected diffusion areas. In other words, if we can find a way to tolerate the alignment error, we will be able to provide significant area reduction.

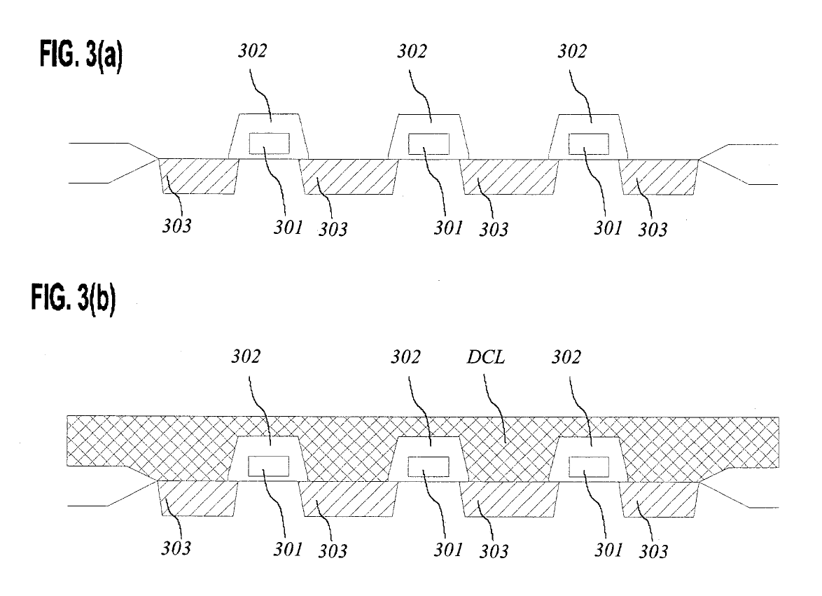

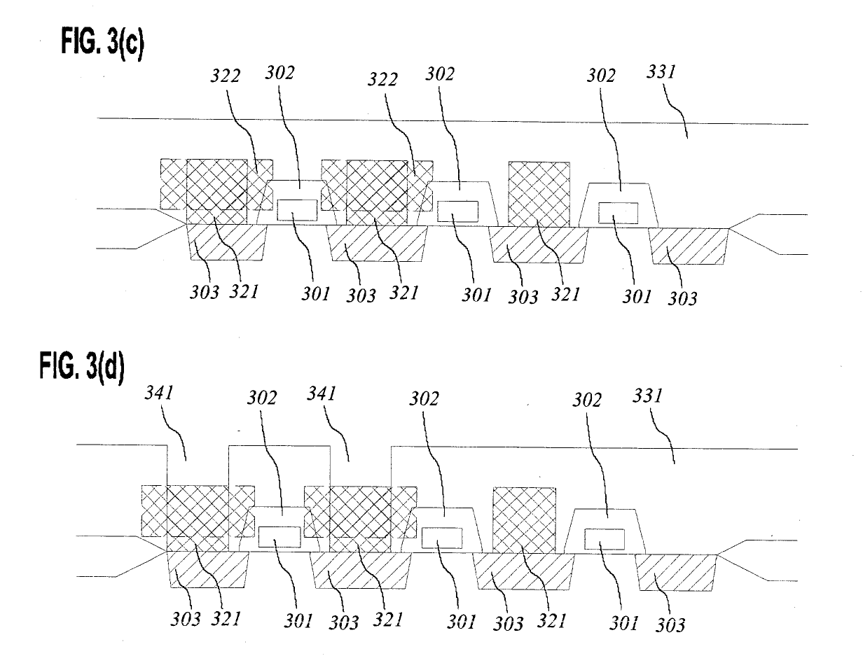

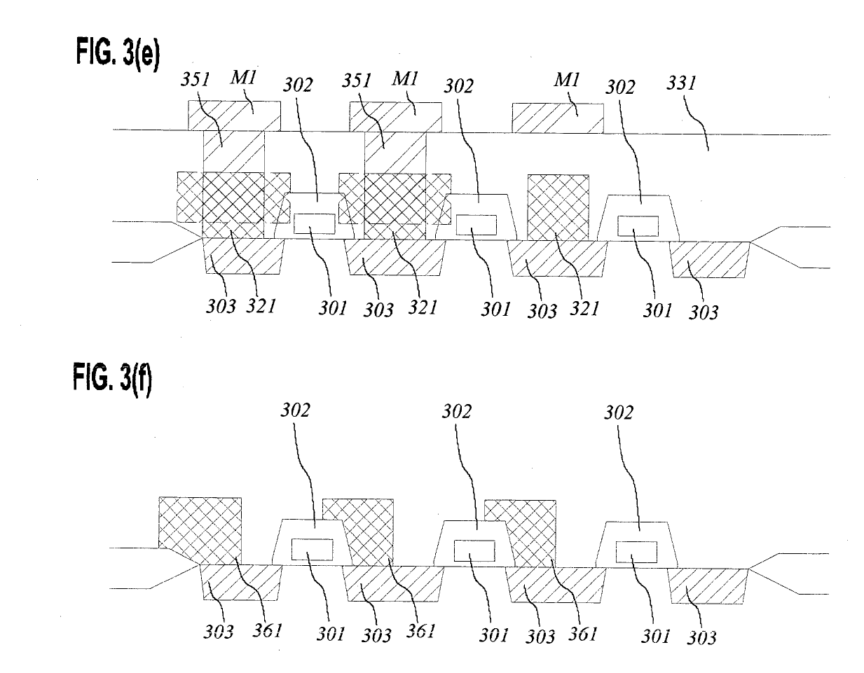

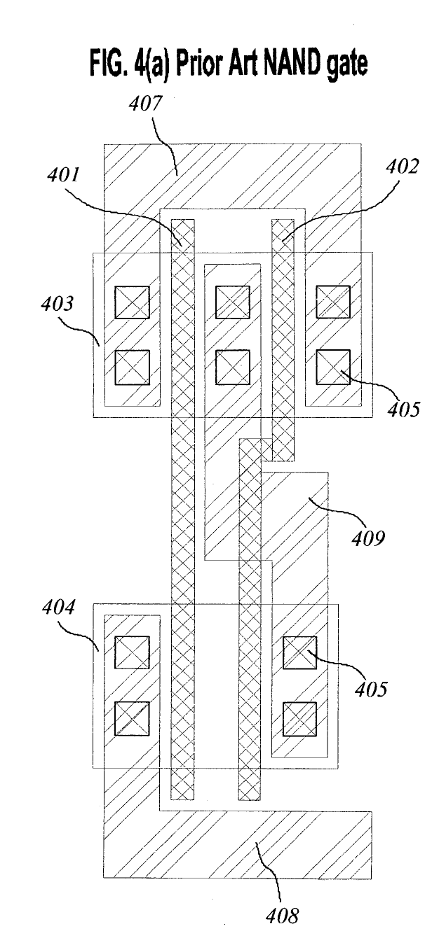

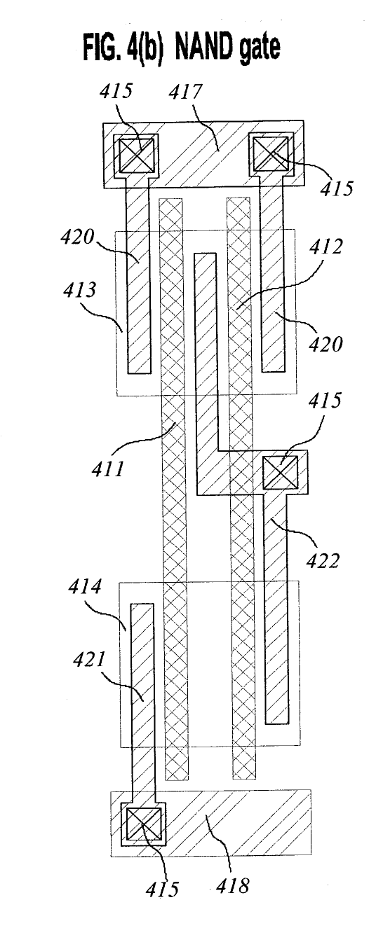

FIGS. 3(a-f) illustrate diffusion connection manufacture procedures of the present invention. FIG. 3(a) shows the cross-section structures of IC devices at the same manufacture stage as FIG. 2(a). At this stage, the manufacture procedures of the present invention are identical to those of prior art IC technologies. The transistor gates (301) are covered with protection oxide (302). The surfaces of diffusion areas (303) are still exposed. Sometimes, at this stage the diffusion area (303) is covered with metallic silicon compound called salicide. We consider salicide as part of diffusion area in our definition. Comparing to prior art structures in FIG. 2(a), the only difference is that we do not need to use larger diffusion areas for connections. For prior art manufacture procedures, the next step is to cover the wafer with insulating layers (211) as shown in FIG. 2(b). For the present invention, the next step is to deposit one or a plurality of conductor layers called “diffusion connection layer” (DCL) as shown in FIG. 3(b). DCL covers the exposed diffusion areas (303) to form high quality connections. The connection pattern of DCL can be defined by similar etching procedures as metal layers, then insulator layers are deposited (331) as shown in FIG. 3(c). The DCL in the diffusion area (321) may have different pattern from the DCL in other areas (322) as also illustrated by the top view in FIG. 4(b). After this step, the remaining manufacture procedures are identical to prior art IC technologies. Contact holes (341) are etched at locations where we want to connect M1 to DCL as shown in FIG. 3(d). DCL allow connections to diffusion areas using contacts away from the diffusion area as shown by the top view in FIG. 4(b). We still can drop contacts on DCL on top of the diffusion area, and we still can have prior art diffusion connection dropped on diffusion areas with DCL etched away. These contact holes (341) are filled and connected to M1 as shown in FIG. 3(e). The DCL is deposited on exposed diffusion areas. It is therefore a self-aligned procedure. If the alignment for DCL etching was off as shown in FIG. 3(f), there is no danger in causing manufacture defects because transistor gates (301) and diffusion (303) edges are protected by oxide that won't be influenced by DCL etching procedures.

Comparing the device structures shown in FIG. 3(e) with the prior art device structures shown in FIG. 2(e), the major difference is that contacts (351) are connected to diffusion through DCL, instead of directly connected to diffusion areas (303). Additional differences are revealed by comparing the top views shown in FIGS. 4(a, b). FIG. 4(a) shows the layout top view of prior art NAND gate. The two inputs (401, 402) of the NAND gate are formed by poly silicon lines. A p-type diffusion area (403) defines two p-channel transistors, and an n-type diffusion area (404) defines two n-channel transistors. The sources of those p-channel transistors are connected to power line (407) through prior art diffusion contacts (405) and M1 lines. The source of one of the n-channel transistor is connected to ground (408) through prior art diffusion contacts (405) and M1 lines. The drains of p-channel transistors are connected to the drain of an n-channel transistor through prior art diffusion contacts (405) and M1 areas to support output signal (409) of this NAND gate. FIG. 4(b) shows the layout top view of a NAND gate of the present invention. This NAND gate has identical function as the gate shown in FIG. 4(a). The two inputs (411, 412) of the NAND gate are formed by poly silicon lines. A p-type diffusion area (413) defines two p-channel transistors and an n-type diffusion area (414) defines two n-channel transistors. DCL (420) forms connection to the sources of those p-channel transistors. The DCL (420) is then connected to M1 power line (417) through contacts (415). Similarly, the source of one of the n-channel transistor is connected to M1 ground line (418) through DCL (421) and contact (415). The drains of p-channel transistors are connected to the drain of an n-channel transistor through DCL (422) to support output signal of this NAND gate. A contact (415) is placed on this DCL (422) to provide connections to other circuits.

For the prior art circuit in FIG. 4(a), the only way to connect a diffusion area is to use a contact (405) on top of diffusion areas (403, 404). Since these diffusion contacts (405) require etching holes right next to transistor gates and diffusion edges, the diffusion areas (403, 404) need to be larger to provide alignment margins. For the circuit of the present invention in FIG. 4(b), a contact (415) can be placed anywhere on top of a DCL. Those contacts (415) can be placed away from gates and diffusion areas so that we no longer need to worry about alignment margins. Even when a contact is placed on top of a DCL close to transistors, the required alignment margin can be smaller than prior art diffusion contacts. The DCL provides reliable self-aligned connections to the diffusion area, while it also provides additional routing capability. The NAND gate of the present invention in FIG. 4(b) is therefore smaller than the prior art NAND gate in FIG. 4(a). Similar area reduction is applicable to most types of circuits. The following table shows the area saving percentages provided by this invention for commonly used circuits fabricated by typical 0.13 um IC technology.

| Circuit Name | Area Saving |
|---|---|
| Inverter | 27% |
| Inverter with two parallel transistors | 32% |
| Two input NAND gate | 32% |
| Three input NAND gate | 34% |
| Four input NAND gate | 35% |
| Two input NOR gate | 32% |
| Three input NOR gate | 34% |
| XNOR gate | 35% |
| Latch | 35% |
| D type flip-flop | 35% |
| D type flip-flop with reset | 33% |
| Single port SRAM cell | 22% |
| Dual port SRAM cell | 32% |
| CAM cell | 35% |
| High density decoder | 39% |

The exact percentage of area saving can vary with design style and detailed design rules, and the numbers maybe quite different from those in the above table. Typically the present invention is able to provide 20%-40% area savings.

Besides area saving, making diffusion area smaller means we have less parasitic capacitor. Prior art diffusion contacts are connected to diffusion at a small area under the contact. The DCL of the present invention can connect to a much larger area so that the quality of connection is by far better. Better performance and less power consumption can be achieved.

A major disadvantage of the present invention is that we need additional manufacture procedures and we may need one additional mask for DCL manufacture. On the other hand, DCL also serves as an additional interconnection layer that can help to achieve better routing efficiency for the overall design. In many cases, using DCL can reduce one high level metal layer, which will save two masking steps (one for metal, one for via). For those cases, the present invention can save one masking step, instead of adding one. DCL also can replace the function of salicide for reduction of diffusion resistance. It is therefore possible to save another manufacture procedure (salicide formation).

While specific embodiments of this invention have been illustrated and described herein, it is realized that other modifications and changes will occur to those skilled in the art. For example, the DCL conductor materials can be poly silicon, Titanium, Tungsten, copper, . . . or a combination of those materials. Detailed procedures and sequences can vary a lot to achieve the same purpose.

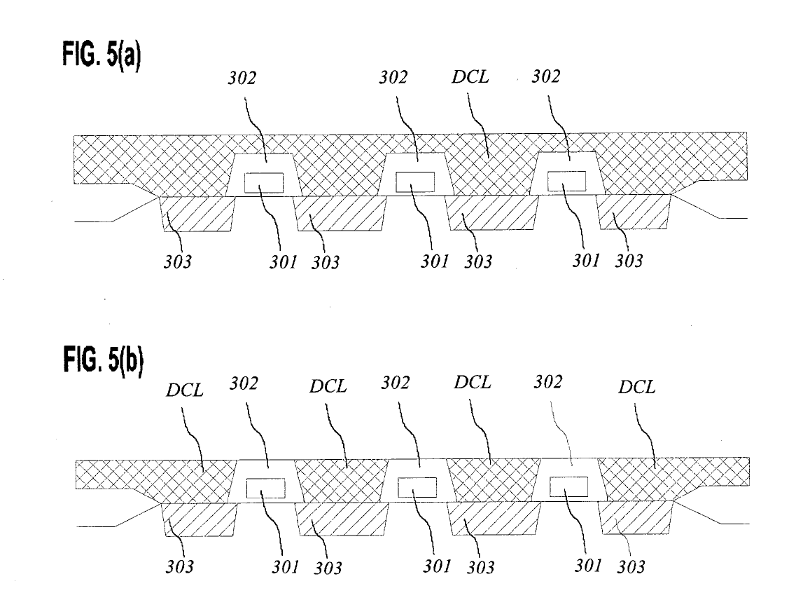

If DCL is defined by masked etching procedures as illustrated in FIG. 3(c), we need to provide enough margin for the spacing between DCL to nearby diffusion. One method to reduce this requirement is illustrated in FIGS. 5(a,b). FIG. 5(a) shows the structures after DCL deposition, and the structures are identical to those in FIG. 3(b). Instead of using a masked etching procedure to define DCL pattern immediately, as shown in FIG. 3(c), we can execute an etch-back procedure to remove DCL layers above gate protection oxide (302) as shown in FIG. 5(b). In this way, the gate protection oxide (302) serve as self-aligned pattern definition boundary for the DCL, and assures there will be no short circuit between DCL and nearby diffusion areas.

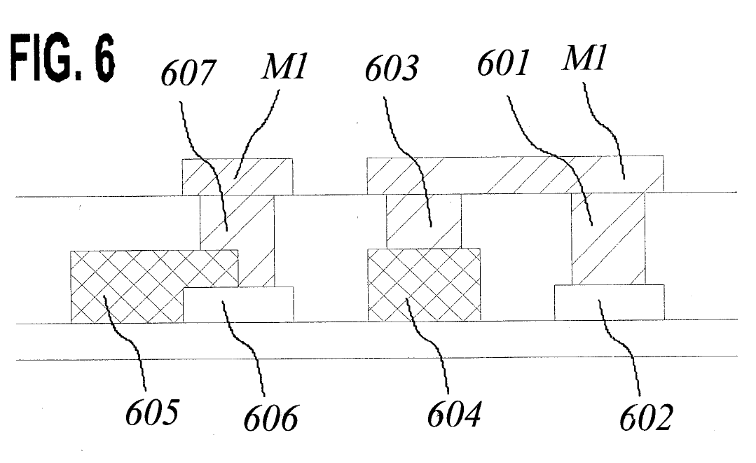

Besides connections to diffusion areas, contacts are also used to connect M1 to other structures such as poly layer. FIG. 6 shows the cross-section structures for a connection between DCL and poly. One method is to use one contact (601) to connect poly (602) to M1, than use another contact (603) to connect DCL (604) to the same piece of M1. Another method is to partially overlap DCL (605) and poly (606) layer as shown in FIG. 6, then etch a contact hole (607) near the overlapping edge. The contact hole etching procedure will etch away the protection oxide on the poly layer so that both DCL and poly surfaces are exposed. The following contact formation procedures will create effective connection between the DCL (605) and poly (606) as illustrated in FIG. 6. Such connection can be connected to M1 if other connections are needed. We also can etch away M1 on top of the contact hole if no other connections are needed.

While specific embodiments of the invention have been illustrated and described herein, it is realized that other modifications and changes will occur to those skilled in the art. It is therefore to be understood that the appended claims are intended to cover all modifications and changes as fall within the true spirit and scope of the invention.

What is claimed is:

1. An integrated circuit manufacture method comprises a procedure to deposit one or a plurality of conductor layers directly on exposed diffusion/salicide areas forming electrical connections to diffusion areas.

2. The integrated circuit manufacture procedure in claim 1 is followed by an etching procedure to define the structures of said conductor layers.

3. The integrated circuit manufacture procedure in claim 1 is followed by an etch back procedure using poly silicon to define boundaries of said conductor layers.

4. A method to form connection between the conductor layers in claim 1 and poly lines by partially overlap said conductor layers with said poly lines, and form connection by the following contact formation on top of said overlapped areas.
